(19) United States
(12) Patent Application Publication
(10) Pub. No.: US 2025/0218955 A1
(43) Pub. Date: Jul. 3, 2025

(54) MICROELECTRONIC STRUCTURES INCLUDING EMBEDDED GLASS PATCH WITH INTEGRATED CAPACITOR

(71) Applicant: Intel Corporation, Santa Clara, CA (US)

(72) Inventors: Jeremy Ecton, Gilbert, AZ (US); Brandon Marin, Gilbert, AZ (US); Srinivas Pietambaram, Chandler, AZ (US); Gang Duan, Chandler, AZ (US); Joshua Stacey, Phoenix, AZ (US); Mahdi Mohammadighaleni, Phoenix, AZ (US); Whitney Bryks, Tempe, AZ (US); Wendy Lin, Chandler, AZ (US); Dilan Seneviratne, Phoenix, AZ (US); Vinith Bejugam, Chandler, AZ (US); Dhruba Pattadar, Chandler, AZ (US)

(73) Assignee: Intel Corporation, Santa Clara, CA (US)

(21) Appl. No.: 18/400,941

(22) Filed: Dec. 29, 2023

(51) Int. Cl. H01L 23/538; H01L 21/48; H01L 23/00; H01L 23/15; H01L 23/64

(52) U.S. Cl. CPC H01L 23/5384; H01L 21/4857; H01L 21/486; H01L 23/15; H01L 23/5383; H01L 23/642; H01L 24/16; H01L 2224/16225

(57) ABSTRACT

Microelectronic integrated circuit package structures include an apparatus having a a glass substrate embedded within a package substrate. The glass substrate comprises one or more trenches extending within a first portion, the one or more trenches comprising a first conductive layer on individual trench sidewalls, a dielectric layer on the first conductive layer and a second conductive layer on the dielectric layer. A second portion of the glass substrate is below the first portion.

### BACKGROUND

In electronics manufacturing, integrated circuit (IC) packaging is a stage of manufacture where an IC that has been fabricated on a die or chip comprising a semiconducting material is coupled to a supporting case or “package” that can protect the IC from physical damage and support electrical interconnect suitable for further connecting to a host component, such as a printed circuit board (PCB). In the IC industry, the process of fabricating a package is often referred to as packaging, or assembly.

Some package architectures may include embedded passive devices, such as deep trench capacitors (DTC) s which may be embedded into a package substrate core. In some cases, a DTC may be fabricated using silicon technology, where a thickness of the DTC is limited to a thickness of a silicon wafer as well as by silicon processing limitations. This thickness limitation can become an issue for a core with a thickness that is greater than 600 microns. Such an embedded silicon based DTC is prone to shifting or rotation within the cavity of the core during and after encapsulation within the core. For example, a thin DTC which is limited to about a 600 micron thickness, when embedded into a core with a thickness that is greater than 600 microns will result in a thickness mismatch between the DTC and the substrate core. This thickness mismatch can lead to significant yield, reliability, and manufacturability challenges. In addition, voiding may occur a result of insufficient filling of encapsulant material as well as vertical and tilt misalignment during embedding.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIGS. 1A-1C are cross-sectional views of IC package structures comprising an embedded glass device, in accordance with some embodiments.

FIGS. 2A-2N are cross-sectional views of IC package structures comprising an embedded glass device, in accordance with some embodiments.

FIGS. 3A-3E are cross-sectional views of IC package structures comprising an embedded glass device, in accordance with some embodiments.

FIG. 4 is a cross-sectional view of an IC package structure comprising an embedded glass device, in accordance with some embodiments.

FIG. 5 illustrates a flow chart of processes for the fabrication of IC package structures having an embedded glass device, in accordance with some embodiments.

FIG. 6 is a functional block diagram of an electronic computing device, in accordance with some embodiments of the present disclosure.

### DETAILED DESCRIPTION

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the explicit context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “dielectric” generally refers to any number of non-electrically conductive materials that make up the structure of a package substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

Views labeled “cross-sectional”, “profile” and “plan” correspond to orthogonal planes within a Cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments discussed herein address problems associated with packaging architectures and methods of embedding passive devices, such as deep trench capacitors (DTC)'s into a package substrate. Embedding capacitors into a substrate core, for example enables the achievement of a fully integrated voltage regulator (FIVR). The embodiments herein include fabricating DTCs on glass panel substrates instead of using silicon materials. Fabricating DTC's on glass panels provides several advantages over silicon DTCs. A primary benefit includes the ability to precisely target a final DTC device thickness using simple and cost-effective wet etching processes for example. DTC thicknesses can be easily tailored to different products and a desired embedding layer (core or build-up layers).

Additionally, glass panel substrates allow for increased DTC design and configuration options, such as enabling simultaneous formation of capacitor structures on two sides of the glass panel and more easily formed through-glass vias (TGVs) compared to through-silicon vias (TSV). Fabricating DTCs on glass substrates results in reduced manufacturing costs due to increased economy of scale from larger panel form factors for glass panels as opposed to silicon wafers. Another advantage is that DTC yield can be decoupled from package substrate yield during fabrication.

Embodiments describe a package substrate comprising a glass substrate embedded within the package substrate. In an embodiment, the glass substrate comprises one or more trenches extending within a first portion. A metal/insulator/metal film stack is formed within individual trenches to form a DTC. A second portion of the glass substrate is below the first portion, wherein the second portion is free of the one or more trenches. In other embodiments, the trenches may be formed on two sides of the glass substrate. Once the glass substrate devices are fabricated to the desired specifications and designs, they can be singulated.

The singulated glass substrate device may then be embedded within a core portion of a package substrate or it may be embedded within a build up portion of the package substrate. Through glass vias (TGV) s may be formed through the glass substrate adjacent to the one or more trenches. An electrical routing structure comprising a redistribution layer (RDL) metallization in some embodiments may be built-up on at least one side of the core portion, and integrated circuit (IC) die(s) may be assembled to interconnect with the routing structure.

The embodiments herein enable a cost-efficient process that can prevent shifting or rotation of DTCs within a package substrate, as well as enabling matching between a thickness of a core layer and a thickness of a DTC.

The architecture described herein may be assembled and/or fabricated with one or more of the features or attributes provided in accordance with various embodiments. A number of different assembly and/or fabrication methods may be practiced to enable passive structures comprising glass substrates, such as DTC's to be reliably embedded within a package structure, according to one or more of the features or attributes described herein.

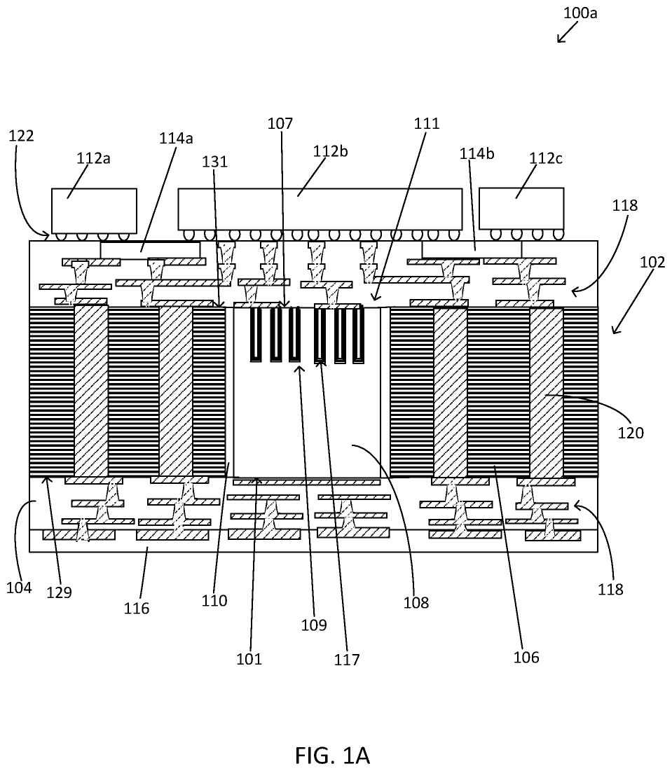

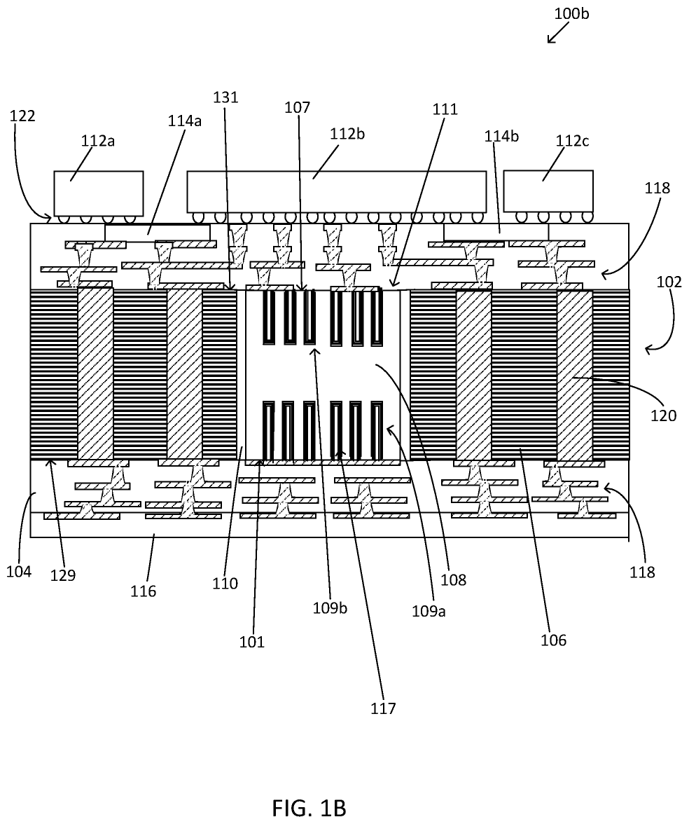

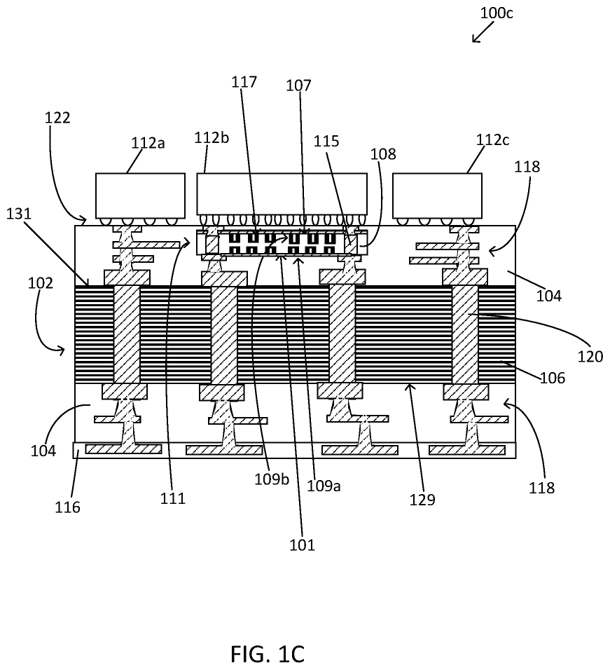

FIGS. 1A-1C illustrate embodiments of package structures including embedded glass patch devices. The package structures are formed utilizing standard deposition and lithographic processing techniques. The methods of fabrication described herein create improved device performance in advanced 2.5D and 3D packaging.

FIG. 1A is a cross-sectional view of a portion of integrated circuit (IC) package structure 100a, in accordance with some embodiments. As shown, a package substrate 102 comprises a core layer 106, wherein the core layer 106 comprises a rigid material, such as epoxy resin or fiberglass-reinforced laminate. The core layer 106 provides mechanical strength and stability to the package substrate 102. A build up layer 104 may be on surfaces 129, 131 of the core layer 106 and may comprise multiple layers of insulating materials and conductive traces that are built on top of the core layer 106 using a sequential build-up process, for example.

A glass substrate 108 is embedded within the core layer 106, wherein surfaces 101, 107 of the glass substrate 108 are coplanar with surfaces 129, 131 of the core layer 106 respectively. In an embodiment, the glass substrate 108 may comprise aluminosilicate, borosilicate, alumino-borosilicate, silica, or fused silica. The glass substrate 108 may include one or more additives, such as A12O3, B2O3, MgO, CaO, SrO, BaO, SnO2, Na2O, K2O, SrO, P2O3, ZrO2, Li2O, Ti, or Zn. In an embodiment, the glass substrate 108 may comprise silicon and oxygen, as well as any one or more of aluminum, boron, magnesium, calcium, barium, tin, sodium, potassium, strontium, phosphorus, zirconium, lithium, titanium, and zinc.

In an embodiment, the glass substrate 108 may comprise at least 23 percent silicon and at least 26 percent oxygen by weight, and further may comprise at least 5 percent aluminum by weight. In an embodiment the glass substrate 108 may comprise a solid layer of glass rectangular in shape in plan view. One or more trenches 109 are within a portion of the glass substrate 108, and may be filled with a film stack 117, such as a metal/insulator/metal film stack, for example. In an embodiment, the film stack may comprise a first conductive material, such as copper, on a trench sidewall, a dielectric material on the first conductive material, and a second conductive material on the dielectric material.

In an embodiment, the glass substrate 108 including the one or more trenches 109 filled with the film stack 117 comprises a deep trench capacitor (DTC) 111. Since the surfaces of the DTC 111 are coplanar with the surfaces of the core 106, the DTC 111 does not shift or rotate within the package substrate 102. Additionally, a thickness of the DTC 111 is matched with a thickness of the core layer 106. In an embodiment, a thickness of the DTC 111 may be greater than about 600 microns. In an embodiment, a thickness of the DTC 111 may be greater than about 1000 microns. In an embodiment, a thickness of the DTC 111 may comprise between about 100 microns to about 2000 microns.

An encapsulant material 110 is between the DTC 111 and the core layer 106. The encapsulant comprises any suitable dielectric or epoxy material, such as a molding material for example. In an embodiment, one or more embedded interconnect bridge structures 114a, 114b may be embedded within the build up layer 106. The embedded interconnect bridge structures 114a, 114b may provide interconnect coupling structures between die, such as die 112a, 112b and 112c. Conductive solder balls 122 couple the die 112a, 112b and 112c to the package substrate 102. Solder balls 122 may comprise any suitable solder ball structures such as silver, gold, tin or copper materials, or combinations thereof, for example.

Conductive trace layers 118 may be distributed within the build up layers 104. Conductive via structures 120 extend through the package substrate 102 to couple the package substrate 102 to devices within and on the package structure 100a. The conductive via structures 120 and conductive traces 118 may comprise a copper material or copper alloys, in an embodiment, but may comprise any suitable conductive material. The conductive via structures 120 and conductive traces 118 form an interconnect path with which to conductively couple any devices coupled within or to the package structure 100a. A passivation layer 116, such as a silicon nitride material for example, may be on a side of the package substrate opposite the die 112a, 112b and 112c.

FIG. 1B is a cross-sectional view of a portion of integrated circuit (IC) package structure 100b, in accordance with some embodiments. As shown, a package substrate 102 comprises a core layer 106, wherein the core layer 106 comprises a rigid material, such as epoxy resin or fiberglass-reinforced laminate. A build up layer 104 may be on surfaces 129, 131 of the core 106 and may comprise multiple layers of insulating materials and conductive traces.

A glass substrate 108 is embedded within the core layer 106, wherein surfaces 101, 107 of the glass substrate 108 are coplanar with surfaces 129, 131 of the core layer 106 respectively. The glass substrate 108 may comprise aluminosilicate, borosilicate, alumino-borosilicate, silica, and fused silica. The glass substrate 108 may include one or more additives, such as Al2O3, B2O3, MgO, CaO, SrO, BaO, SnO2, Na2O, K2O, SrO, P2O3, ZrO2, Li2O, Ti, and Zn. The glass substrate 108 may comprise silicon and oxygen, as well as any one or more of aluminum, boron, magnesium, calcium, barium, tin, sodium, potassium, strontium, phosphorus, zirconium, lithium, titanium, and zinc, and may comprise at least 23 percent silicon and at least 26 percent oxygen by weight.

In an embodiment the glass substrate 108 may comprise a solid layer of glass

rectangular in shape in plan view. A first set of one or more trenches 109a are within a portion of a first side 101 of the glass substrate 108, and a second set 109b of the one or more trenches 109b are within a portion of the second side 107 of the glass substrate 108. The first and second sets of the one or more trenches 109a, 109b may be filled with a film stack 117, such as a metal/insulator/metal film stack, for example, although any other suitable film stack may be formed within the one or more trenches according to a particular application.

In an embodiment, the glass substrate 108 including the one or more trenches 109a, 109b filled with the film stack 117 comprises a DTC 111. Since the surfaces of the DTC 111 are coplanar with the surfaces of the core 106, the DTC 111 does not shift or rotate within the package substrate 102. Additionally, a thickness of the DTC 111 is matched with a thickness of the core layer 106. In an embodiment, a thickness of the DTC 111 may be greater than about 600 microns. In an embodiment, a thickness of the DTC 111 may be greater than about 1000 microns.

FIG. 1C is a cross-sectional view of a portion of integrated circuit (IC) package structure 100c, in accordance with some embodiments. As shown, a package substrate 102 comprises a core layer 106 and a build up layer 104 on surfaces 129, 131 of the core layer 106. A glass substrate 108 is embedded within the build up layer 104. The glass substrate 108 may comprise aluminosilicate, borosilicate, alumino-borosilicate, silica, and fused silica. The glass substrate 108 may include one or more additives, such as Al2O3, B2O3, MgO, CaO, SrO, BaO, SnO2, Na2O, K2O, SrO, P2O3, ZrO2, Li2O, Ti, and Zn. The glass substrate 108 may comprise silicon and oxygen, as well as any one or more of aluminum, boron, magnesium, calcium, barium, tin, sodium, potassium, strontium, phosphorus, zirconium, lithium, titanium, and zinc, and may comprise at least 23 percent silicon and at least 26 percent oxygen by weight.

In an embodiment the glass substrate 108 may comprise a solid layer of glass rectangular in shape in plan view. A first set of one or more trenches 109a are within a portion of a first side 101 of the glass substrate 108, and a second set 109b of the one or more trenches 109b are within a portion of the second side 107 of the glass substrate 108. The first and second sets of the one or more trenches 109a, 109b may be filled with a film stack 117, such as a metal/insulator/metal film stack, for example.

In an embodiment, the glass substrate 108 including the one or more trenches 109a, 109b filled with the film stack 117 comprises a DTC 111. In an embodiment, through glass vias (TGV) s 115 extend through the glass substrate 108 and are adjacent to the first and second sets of the one or more trenches 109a, 109b. The TGVs may be filled with a conductive material, such as copper for example. In an embodiment, a thickness of the DTC 111 may be less than about 1000 microns and may be optimized to enable the embedding of the DTC 111 within the build up layer 104. In an embodiment, a thickness of the DTC 111 may be between about 25 microns to about 250 microns. Conductive trace layers 118 may be distributed within the build up layers 104 and conductive via structures 120 extend through the package substrate 102 to couple the package substrate 102 to devices within and on the package structure 100c. A passivation layer 116, such as a silicon nitride material for example, may be on a side of the package substrate opposite the die 112a, 112b and 112c.

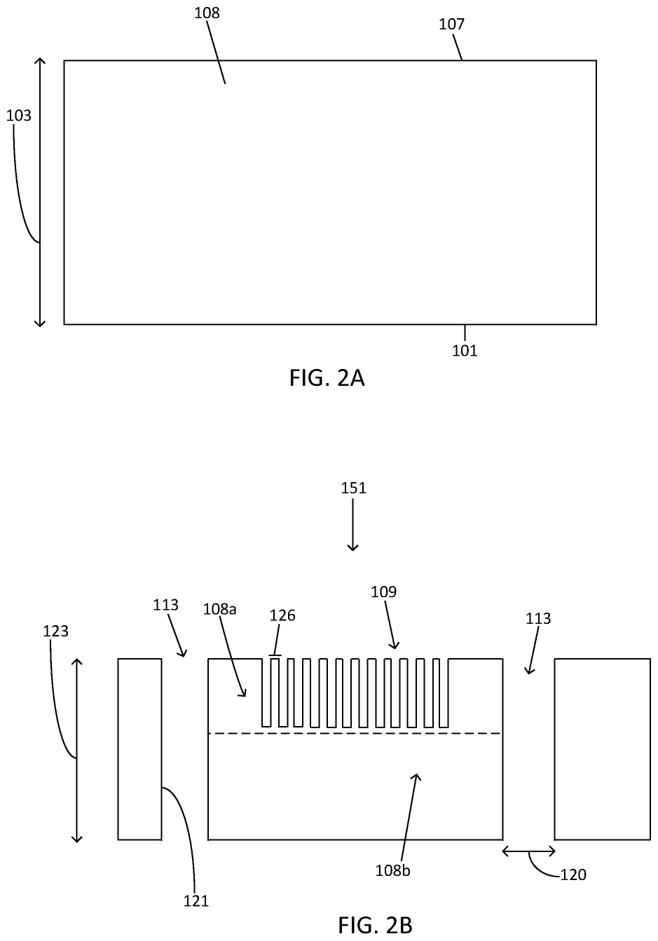

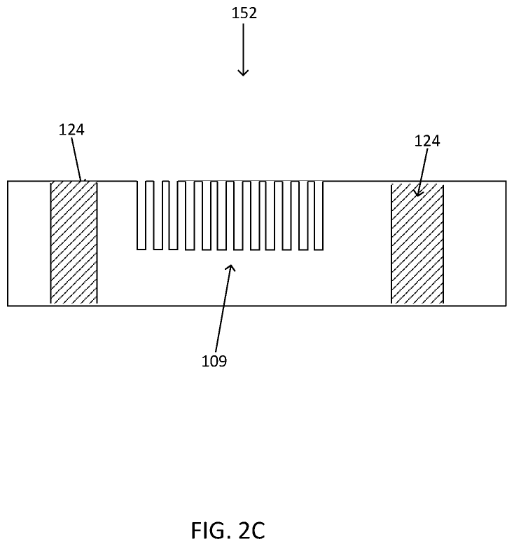

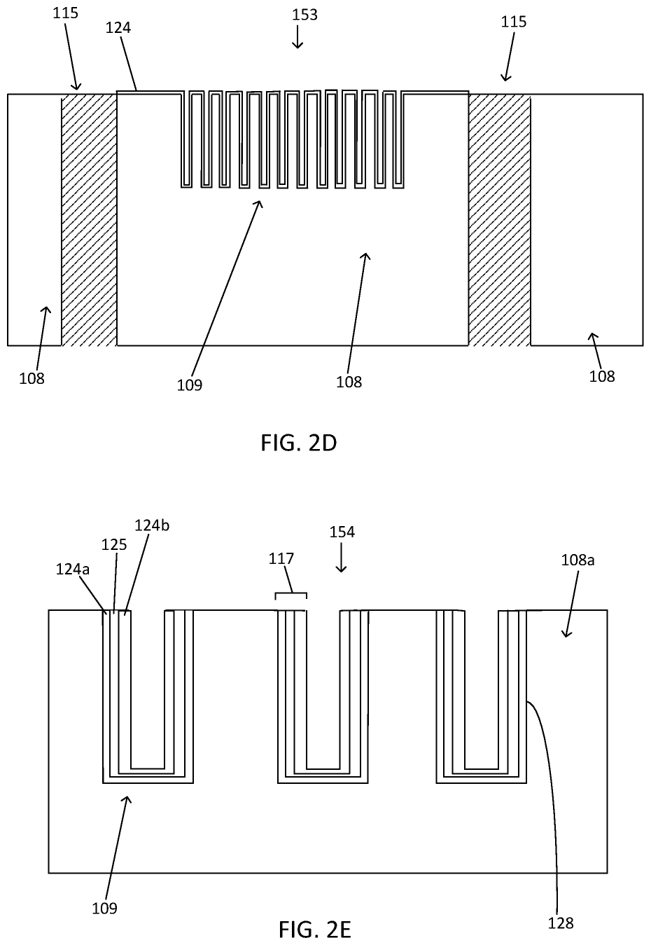

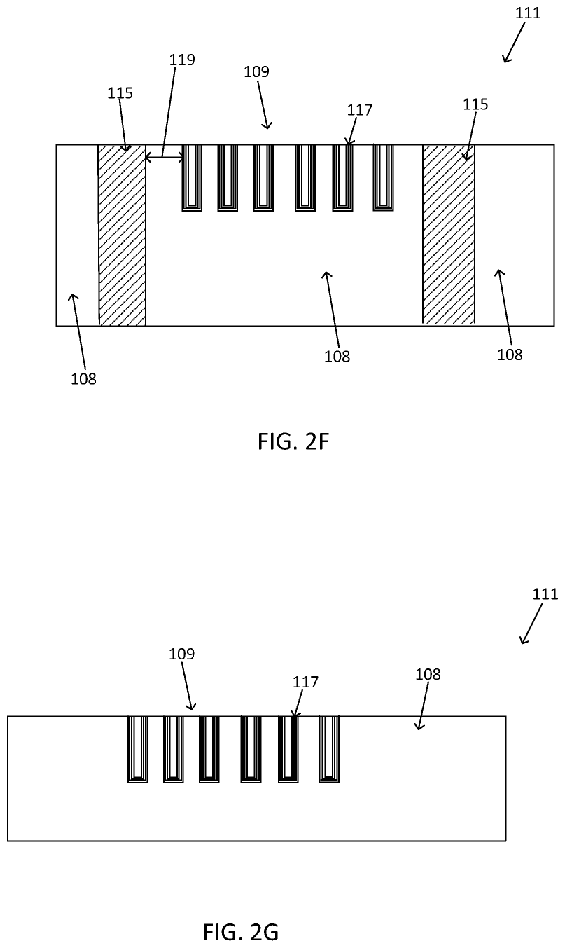

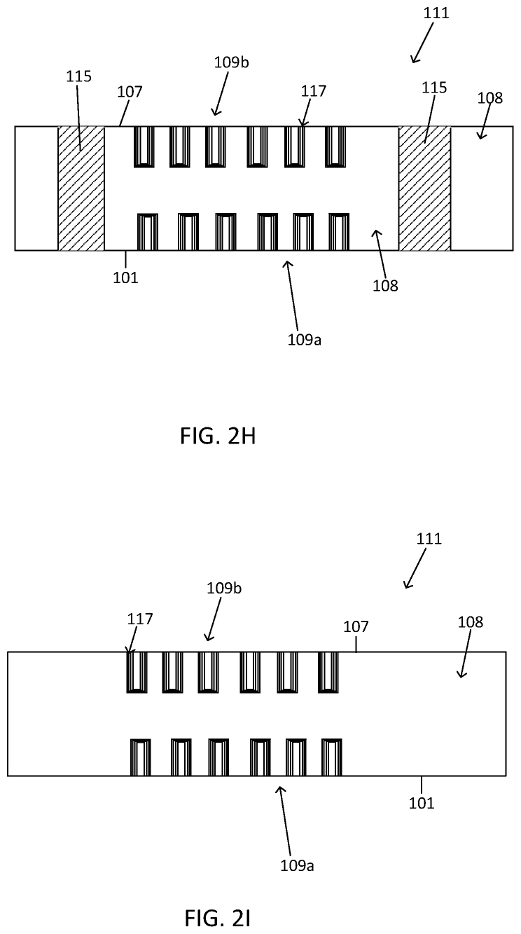

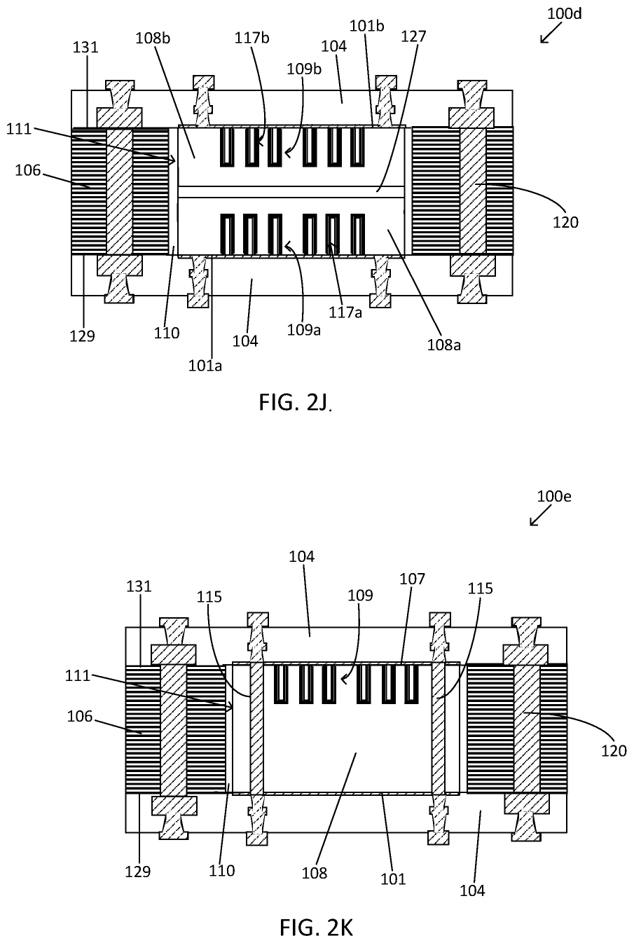

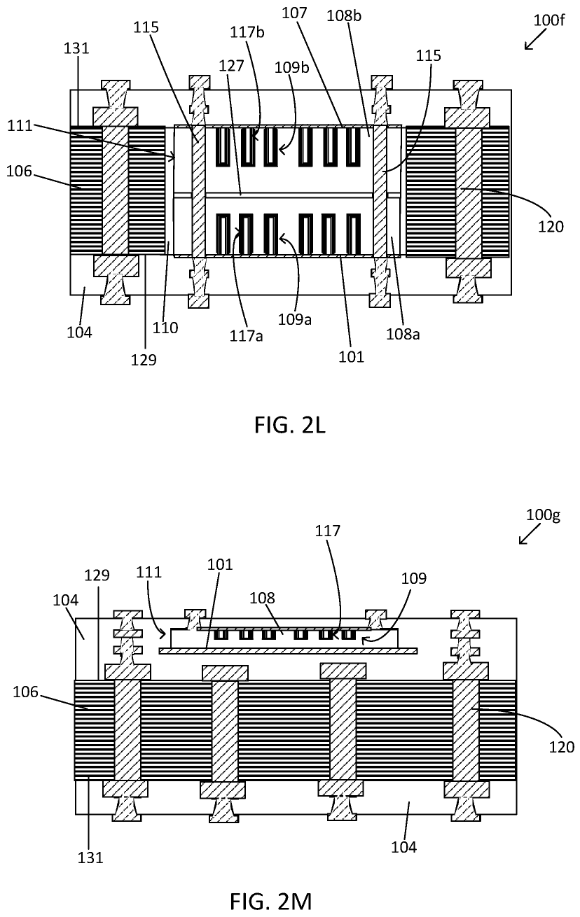

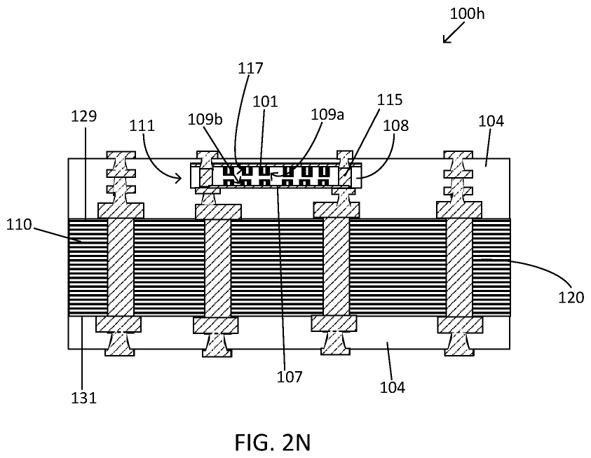

FIGS. 2A-2M illustrate embodiments of forming IC package structures (such as the IC package structures of (FIGS. 1A-1C), for example. FIG. 2A depicts a cross-sectional view of a portion of a substrate 108 according to some embodiments. As shown, the substrate 108 may comprise a glass substrate 108. IC device package structures may be fabricated upon glass substrate 108. Glass substrate 108 may comprise a solid bulk material layer that may have been previously formed into any shape in plan view (e.g., x-y plane) suitable for a packaging workpiece, such as rectangular shape. Glass substrate 108 may comprises a thickness 103 which may be optimized according to particular design requirements, for example to limit warpage while remaining thin enough to permit the formation of through glass vias (TGVs) at a pitch which is optimized for particular design requirements. In exemplary embodiments, the thickness 103 may comprise above 600 microns.

Glass substrate 108 is advantageously predominantly silicon and oxygen. In some embodiments, substrate 108 comprises at least 23 percent silicon and at least 26 percent oxygen, by weight (i.e., wt. %). Substrate 108 may further include one or more additives, such as, aluminum, boron, magnesium, calcium, barium, tin, sodium, potassium, strontium, phosphorus, zirconium, lithium, titanium, or zinc. In some embodiments where substrate 108 comprises at least 23 wt. % Si and at least 26 wt. % O, substrate 108 further comprises at least 5 wt. % Al. Additives within substrate 108 may form suboxides (A2O) monoxides (AO), binary oxides (AO2), ternary oxides (ABO3), and mixtures thereof. For example, substrate 102 may comprise AlOx (e.g., Al2O3), BOx (e.g., B2O3), MgOx (e.g., MgO), CaOx (e.g., CaO), SrOx (e.g., SrO), BaOx (e.g., BaO), SnOx (e.g., SnO2), NaOx (e.g., Na2O), KOx (e.g., K2O), POx (e.g., P2O3), ZrOx (e.g., ZrO2), LiOx (e.g., Li20), TiOx (e.g., TiO2), or ZnOx (e.g., ZnO2). Depending on chemical composition, substrate 108 may therefore be referred to as silica, fused silica, aluminosilicate, borosilicate, or alumino-borosilicate, for example.

Glass substrate 108 is advantageously a bulk material of substantially homogeneous composition in contrast to a composite material that may merely comprise glass fillers and/or fibers. Although glass substrate 108 is substantially amorphous in some embodiments, glass substrate 108 may also have other morphology or microstructure, such as polycrystalline (e.g., nanocrystalline). The glass substrate 108 may comprise a pre-etch thickness 103, a first side 101 and a second side 107.

In FIG. 2B, a process 151 may be employed to form one or more trenches 109 within and through a first portion 108a of the glass substrate 108. A second portion 108b is free of the one or more trenches 109 in an embodiment. Process 151 may comprise such processes as a wet or dry etch process, or a laser assisted process. In an embodiment, any process known to be suitable for forming trenches in bulk glass may be utilized. In some embodiments, a laser ablation process, a glass etch process (laser-assisted, or otherwise), or any other such techniques known to be suitable for forming features through a thickness of the glass substrate 108 may be employed to achieve a desired diameter and feature pitch of the one or more trenches 109 within the first portion 108a of the glass substrate 108.

In an embodiment, the first portion 108a of the glass substrate 108 may comprise less than about 50 percent of a post etch thickness 123 of the glass substrate, in another embodiment, the first portion 108a of the glass substrate 108 may comprise less than about 35 percent of a post etch thickness 123 of the glass substrate. The post etch thickness 123 of the glass substrate 108 may comprise a target thickness according to the placement of the glass substrate 108 within a package substrate. For example, the post etch thickness 123 may be targeted to be substantially equal to a package core thickness. In another embodiment, the post etch thickness 123 may be targeted to be less than a thickness of a build up layer of a package substrate. In an embodiment, a pitch 126 between individual one of the one or more trenches 109 may comprise between about 1 micron and 10 microns but may be optimized depending upon the particular application. In an embodiment, a lateral width of the one or more trench openings may be between 1 micron to 15 microns.

In an embodiment, a through glass via opening 113 (TGV) may be formed during process 151 adjacent to the one or more trenches 109. The TGV opening 113 may extend through the glass substrate 108 and may comprise a sidewall 121. In another embodiment, the TGV opening 113 may not be formed adjacent to the one or more trenches, as depicted in FIG. 1A, for example.

In FIG. 2C, a process 152 may be employed to form a conductive material 124 within the TGVs 113. The process 152 may comprise any suitable process, such as a plating process 152. In FIG. 2D, a conductive material 124 may be formed within the one or more trenches 109 utilizing a formation process 153. The formation process 153 may comprise any suitable physical deposition process such as a plasma deposition process for example. In an embodiment, the formation process 153 may comprise a chemical vapor deposition (CVD) process, an atomic layer deposition (ALD) process or a sputter process followed by a patterning process.

In an embodiment the formation process 153 may comprise electroless formation process or any other suitable wet formation processes. The conductive material 124 may comprise a copper material 124 or copper alloys, in an embodiment, but may comprise any suitable conductive material. The conductive material 124 forms an interconnect path with which to conductively couple to any devices within or on a package structure. The conductive material 124 may comprise a portion of a passive device formed within the glass substrate 108, such as a deep trench capacitor or an inductor, for example.

FIG. 2E depicts a section of the first portion 108a of the glass substrate 108 wherein a film stack 117 comprising a metal/insulator/metal (MIM) film stack may be formed using formation process 154 within the one or more trenches 109. In an embodiment, the process 154 may comprise such processes as chemical vapor deposition (CVD) or physical vapor deposition (PVD), for example. In an embodiment, a first conductive material 124a may be formed on a sidewall 128 of the one or more trenches 109, wherein the sidewall 128 may comprise a sidewall of the glass substrate 108.

In an embodiment, the first conductive material 124a may comprise copper or a copper alloy but may comprise any suitable conductive material. In an embodiment, a dielectric material 125 may be formed on the conductive material. The dielectric material 125 may comprise a silicon oxide or a silicon nitride material, in an embodiment, but may comprise any suitable dielectric material. A second conductive material 124b may be formed on the dielectric material 125, wherein the second conductive material 124b may comprise the same or a different conductive material as the first conductive material 124a. In an embodiment, any suitable combinations of film layers/materials may be formed within the one or more trench openings utilizing process 154, such as an inductor film stack.

FIG. 2F depicts a deep trench capacitor (DTC) structure 111 comprising one or more trenches 109 within the glass substrate 108. The one or more trenches 109 comprise a film stack 117 comprising a metal/insulator/metal (MIM) film stack. TGVs 115 are adjacent to the one or more trenches, wherein there is a distance 119 between the one or more trench openings 109 and the TGVs. The TGVs are filled with a conductive material, such as a copper material. FIG. 2G depicts another embodiment of a DTC structure 111 comprising one or more trenches 109 within the glass substrate 108 with a MIM film stack 117. In an embodiment, the DTC structure 111 does not comprise TGV structure adjacent to the one or more trenches.

FIG. 2H depicts another embodiment of a DTC structure 111 comprising a first set of one or more trenches 109a on a first side 101 of a glass substrate 108, and a second set 109b of one or more trenches 109b on a second side 107 of the glass substrate 108. The first and second sets of one or more trenches 109a, 109b may be formed utilizing processes as described previously herein. A MIM film stack 117 is within individual ones of the first and second sets of the one or more trenches 109a, 109b. TGV structures 115 are adjacent to the first and second sets of the one or more trenches 109a, 109b.

FIG. 2I depicts another embodiment of a DTC structure 111 comprising a first set of one or more trenches 109a on a first side 101 of a glass substrate 108, and a second set 109b of one or more trenches 109b on a second side 107 of the glass substrate 108. A MIM film stack 117 is within individual ones of the first and second sets of the one or more trenches 109a, 109b. In an embodiment, no TGVs are adjacent to the first and second sets of the one or more trenches 109a, 109b.

FIG. 2J depicts a portion of a package structure 100d wherein a DTC structure 111 comprises a first substrate 108a hybrid bonded to a second substrate 108b. The DTC structure 111 is embedded in a core portion 106 of the package structure 100d. A hybrid bond 127 is between the first and second glass substrates 108a, 108b. A first set of one or more trenches 109a is within the first glass substrate 108a, and a second set 109b of one or more trenches 109b is within the second glass substrate 108b. First and second MIM film stacks 117a, 117b are within individual ones of the first and second sets of the one or more trenches 109a, 109b.

A first side 101a of the first substrate 108a is coplanar with a first side 129 of the core portion 106 and first side 101b of the second glass substrate 108b is coplanar with a second side 131 of the core portion 106. Build up layers 104 are on the first sides 101a, 101b of the first and second glass substrates 108a, 108b respectively. A mold material 110 is between the core material 106 and the first and second glass substrates 108a, 108b. The mold/encapsulant material 110 is between the hybrid bond region 127 and the core 106.

In FIG. 2K, a portion of a package structure 100e is depicted wherein a DTC structure 111 comprises one or more trenches 109 within a glass substrate 108. MIM film stacks 117 are within individual ones of the one or more trenches 109. TGVs 115 are adjacent to the one or more trenches 109 and extend through the glass substrate 108. The DTC structure 111 is embedded in a core portion 106 of the package structure 100e. A first side 101 of the glass substrate 108 is coplanar with a first side 129 of a core portion 106 and second side 107 of the glass substrate 108 is coplanar with a second side 131 of the core portion 106. Build up layers 104 are on the first side 101 and second side 107 of the glass substrate 108. A mold material 110 is between the core material 106 and the glass substrate 108. Conductive structures 120 extend through the core material 106.

In FIG. 2L, a portion of a package structure 100f wherein a DTC structure 111 comprises a first substrate 108a hybrid bonded to a second substrate 108b. The DTC structure 111 is embedded in a core portion 106 of the package structure 100f. A hybrid bond 127 is between the first and second glass substrates 108a, 108b. A first set of one or more trenches 109a is within the first glass substrate 108a, and a second set 109b of one or more trenches 109b is within the second glass substrate 108b. First and second MIM film stacks 117a, 117b are within individual ones of the first and second sets of the one or more trenches 109a, 109b. TGVs 115 extend through the first and second substrates 108a, 108b and are adjacent to the one or more trenches 109a, 109b.

A first side 101 of the DTC 111 is coplanar with a first side 129 of the core portion 106 and second side 107 of the DTC 111 is coplanar with a second side 131 of the core portion 106. Build up layers 104 are on the first side 101 and second side 107 respectively of the DTC 111. A mold material 110 is between the core material 106 and sidewalls of the DTC 111. The mold material 110 is between the hybrid bond region 127 and the core 106.

In FIG. 2M, a portion of a package structure 100g is depicted wherein a DTC structure 111 comprises one or more trenches 109 within a glass substrate 108. MIM film stacks 117 are within individual ones of the one or more trenches 109. The DTC structure 111 is embedded in a build up portion 104 of the package structure 100g . A first side 101 of the glass substrate 108 is over a first side 129 of a core portion 106. Build up layers 104 are on the first side 129 and second side 131 of the core portion 106. Conductive structures 120 extend through the core material 106.

In FIG. 2N, a portion of a package structure 100h is depicted wherein a passive structure, such as a DTC structure 111, comprises a first set of one or more trenches 109a on a first side 101 of a glass substrate 108, and a second set 109b of one or more trenches 109b on a second side 107 of the glass substrate 108. A MIM film stack 117 is within individual ones of the first and second sets of the one or more trenches 109a, 109b. TGVs 115 extend through the glass substrate 108, and are adjacent to the one or more trenches 109a, 109b. The DTC structure 111 is embedded in a build up portion 104 of the package structure 100g. The first side 101 of the glass substrate 108 is over a first side 129 of a core portion 106. Build up layers 104 are on the first side 129 and second side 131 of the core portion 106. Conductive structures 120 extend through the core material 106.

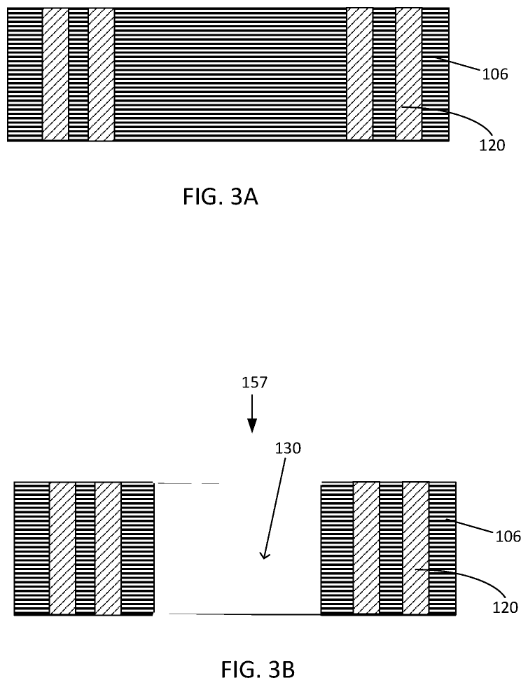

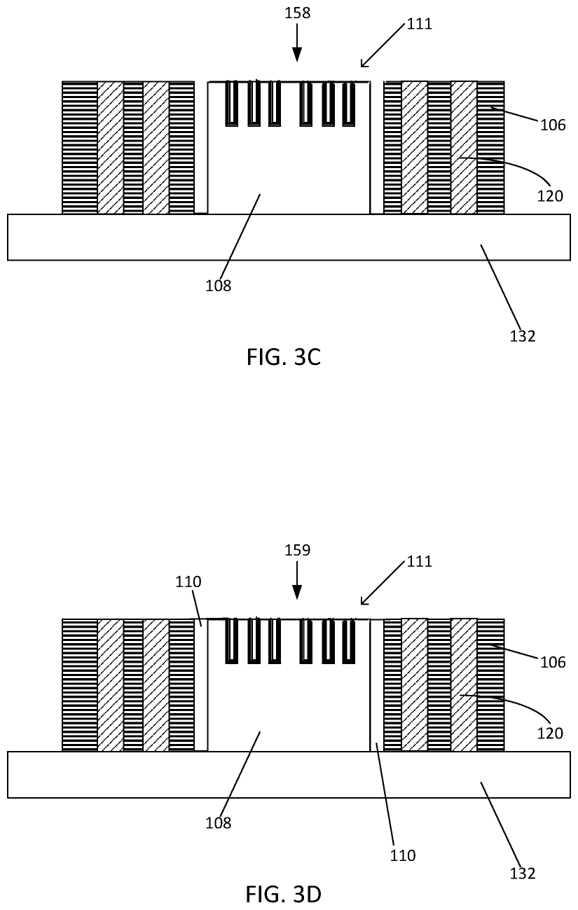

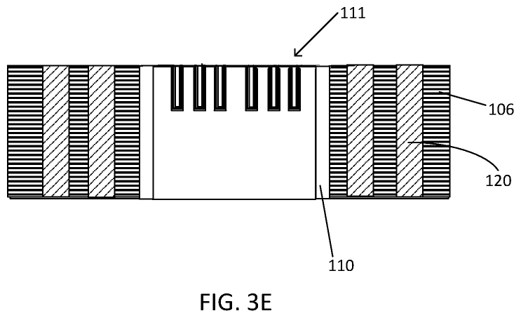

FIGS. 3A-3E depict a method of placing a passive device, such as a DTC within a package substrate core for use in a package substrate. FIG. 3A depicts a portion of a package core 106 with conductive via structures 120 extending through the package core. In FIG. 3B, a process 157 removes a portion of the core 106. The process 157 may include any suitable etching or drilling process to remove the portion of the core 106 to expose a core cavity 130. In FIG. 3C, a glass substrate DTC 111 according to embodiments herein, is placed within the core cavity 130 using a placement process 158 such as a pick and place process 158. The DTC 111 is on a carrier 132. In an embodiment, a bond tape may be used to attach the DTC 111 to the carrier 132. In FIG. 3D, an encapsulation process 159 may be employed wherein an encapsulant material 110 may be formed within the space between the core 106 and the DTC and may be formed on the DTC 111. The encapsulant material 110, such as a dielectric material, for example, may then be removed from the surface of the DTC 111 and planarized by using such processes as chemical mechanical polishing (CMP). In FIG. 3E the carrier 132 may be removed from the DTC 111.

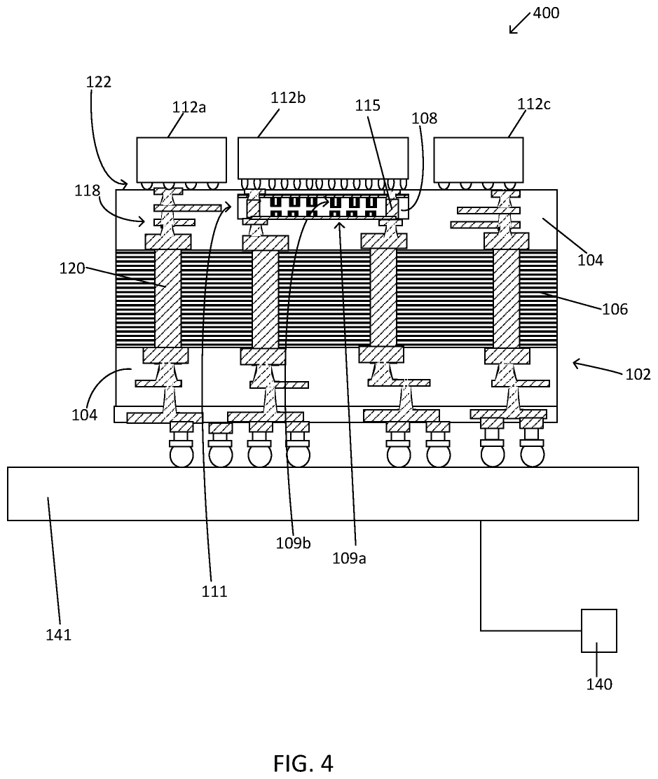

FIG. 4 depicts an IC package structure 400, wherein dies 112a, 112b and 112c are on a package substrate 102, such as a package substrate 102 of FIG. 1A, for example. In some embodiments, the dies 112a, 112b and 112c may comprise chiplet structures 112a, 112b and 112c which may comprise components of a system on a chip (SOC) structure. The dies 112a, 112b and 112c are coupled to each other and to a glass substrate 108 including TGV vias 115 adjacent to a one or more trenches 109a, 109b of a passive device 111 such as a DTC 111, according to any of the embodiments disclosed herein, through a redistribution layer (RDL) metallization 118. The device 111 is shown as embedded in a build up layer 104, but may also be embedded and coplanar with a core material 106, as depicted in other embodiments disclosed herein.

Any number of die/devices may be couple to the substrate 102. The substrate 102 may be coupled to a board 141, such as a printed circuit board, in an embodiment. Conductive bumps 122 may comprise any conductive element for coupling to an outside die or other device. In an embodiment, the conductive bumps 122 may include silver, tin, or copper, or combinations or alloys thereof. Conductive vias 120 extend through the core 106 and build up material 104 to couple with the board 141. A power supply 140, which may comprise any suitable power supply as known in the art, may be coupled to dies 112a, 112b and 112c via IC package structure 400, in an embodiment.

Discussion now turns to operations for assembling and/or fabricating the discussed structures.

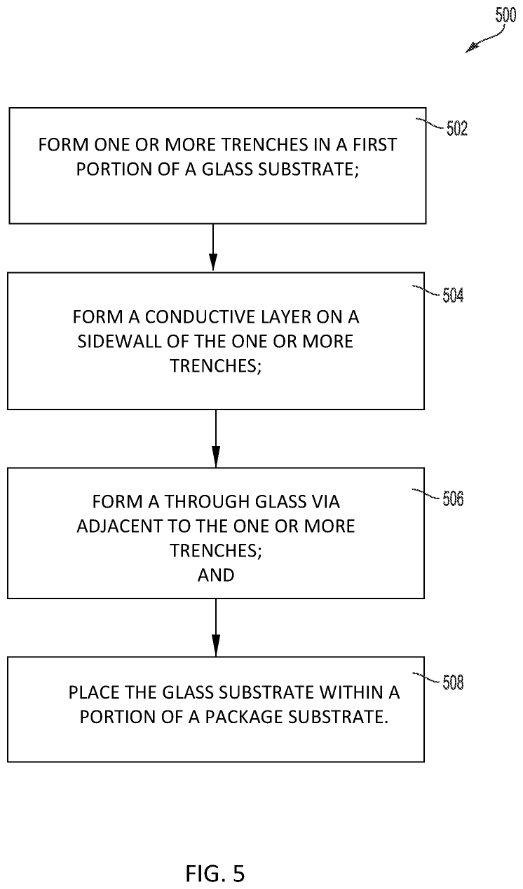

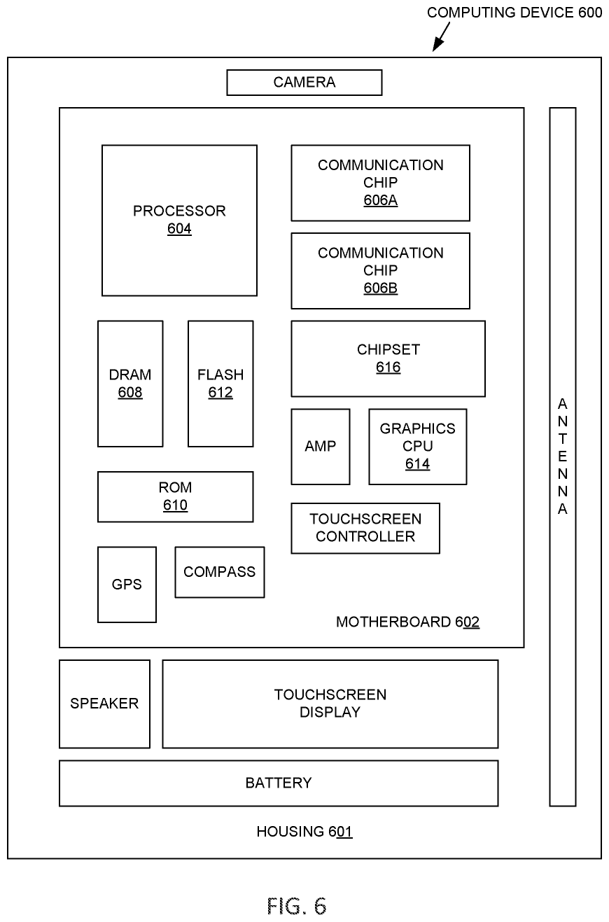

FIG. 5 is a flow chart of a process 500 of fabricating package structures according to some embodiments. For example, process 500 may be used to fabricate any of the microelectronic IC package structures of FIGS. 2A-2M.

As set forth in block 502, one or more trenches are formed in a first portion of a glass substrate. In an embodiment, the glass substrate may comprise a layer of glass. In an embodiment, the layer of glass may comprise aluminosilicate, borosilicate, alumino-borosilicate, silica, and fused silica. The layer of glass may include one or more additives, such as Al2O3, B2O3, MgO, CaO, SrO, BaO, SnO2, Na2O, K2O, SrO, P2O3, ZrO2, Li2O, Ti, and Zn. The layer of glass may comprise silicon and oxygen, as well as any one or more of aluminum, boron, magnesium, calcium, barium, tin, sodium, potassium, strontium, phosphorus, zirconium, lithium, titanium, and zinc. The layer of glass may comprise at least 23 percent Silicon and at least 26 percent Oxygen by weight, and further comprising at least 5 percent Aluminum by weight. The layer of glass may be a solid bulk material layer that may have been previously formed into any shape in plan view (e.g., x-y plane) suitable for a packaging workpiece, such as rectangular. In an embodiment, the layer of glass has a thickness that may vary with implementation, for example to limit warpage while remaining thin enough to permit the formation of through vias at a pitch as small as is enabled by the surface flatness of the layer of glass. In an embodiment, a thickness of the layer of glass is advantageously 200 microns to 2000 microns.

The layer of glass is advantageously predominantly silicon and oxygen. In some embodiments, the layer of glass comprises at least 23 percent silicon and at least 26 percent oxygen, by weight (i.e., wt. %). In some embodiments where the layer of glass comprises at least 23 wt. % Si and at least 26 wt. % O, the layer of glass further comprises at least 5 wt. % Al. Additives within glass may form suboxides (A2O) monoxides (AO), binary oxides (AO2), ternary oxides (ABO3), and mixtures thereof. For example, glass may comprise AlOx (e.g., Al2O3), BOx (e.g., B2O3), MgOx (e.g., MgO), CaOx (e.g., CaO), SrOx (e.g., SrO), BaOx (e.g., BaO), SnOx (e.g., SnO2), NaOx (e.g., Na2O), KOx (e.g., K2O), POx (e.g., P2O3), ZrOx (e.g., ZrO2), LiOx (e.g., Li2O), TiOx (e.g., TiO2), or ZnOx (e.g., ZnO2). Depending on chemical composition, glass may therefore be referred to as silica, fused silica, aluminosilicate, borosilicate, or alumino-borosilicate, for example.

In an embodiment, the glass substrate may be thinned utilizing any appropriate glass etching process, such as a laser assisted process or a wet or dry etch process, for example. The glass substrate may be thinned to a target thickness, which may be determined with respect to the location where the glass substrate is to be placed. For example, in an embodiment, when the glass substrate is to be placed within a core of a substrate package, the glass substrate may be thinned to a thickness of the core such that a thickness of the glass substrate is substantially the same as a thickness of the substrate core. In another embodiment, when the glass substrate is to be placed within a build up portion of a substrate package, the glass substrate may be thinned to a thickness that is appropriate for the placement of the glass substrate within the build up layer, where the build up layer is on the core portion of the substrate package.

In an embodiment, a thickness of the first portion of the glass substrate may comprise less than about 50 percent of a total thickness of the glass substrate. In an embodiment, the thickness of the first portion the glass substrate may comprise less than about 30 percent of the thickness of the glass substrate. In an embodiment, the one or more trenches may be formed by utilizing any appropriate glass etching process, such as a laser assisted etch process or a dry etch process, for example. In an embodiment, the one or more trenches may comprise about a 30:1 aspect ratio, and a pitch of about 1 micron to about 15 microns between individual ones of the one or more trenches. In another embodiment, the one or more trenches may comprise a pitch of about 15 microns to about 50 microns between individual ones of the one or more trenches. In an embodiment, the one or more trenches may be formed simultaneously with the thinning process of the glass substrate.

In an embodiment, a first set of the one or more trenches may be formed in a first side of the glass substrate, and a second set of the one or more trenches may be formed in a second side of the glass substrate, wherein the first side is opposite the second side of the glass substrate, as depicted in FIG. 1B, for example. In another embodiment, a first glass substrate comprising a first set of trenches may be hybrid bonded to a second glass substrate comprising a second set of trenches, as depicted in FIG. 21, for example. The hybrid bond may be formed using hybrid bonding techniques as are known in the art.

At step 504, a conductive layer may be formed on a sidewall of the one or more trenches. In an embodiment, a first conductive layer may be formed within the one or more trenches and may comprise copper or copper alloy materials. The first conductive material may be formed using any suitable formation process, such as a physical deposition process, for example. In an embodiment, a dielectric material may be formed on the first conductive material within the one or more trenches. The dielectric material may comprise any suitable dielectric material such as a silicon dioxide or a silicon nitride material for example.

Subsequently, a second conductive material may be formed on the dielectric material, such that a metal/insulator/metal (MIM) structure may be formed within individual trenches of the one or more trenches. The MIM structure may comprise a capacitor structure with electrical contacts to electrically couple to a package substrate. In other embodiments, passive structures such as an inductor may be formed within the one or more trenches depending upon the particular application requirements.

At step 506, a through glass via (TGV) may be formed adjacent to the one or more trenches. In an embodiment, a TGV may be formed in peripheral regions of the glass substrate, adjacent to the one or more trenches. In an embodiment, the TGV may be formed before or after the one or more trenches are formed. In an embodiment, the TGV extends through the entire thickness of the glass substrate. The TGV may be formed utilizing drilling or chemical etching processes. In an embodiment, any process known to be suitable for forming TGVs in bulk glass may be utilized. In some embodiments, a laser ablation process, a glass etch process (laser-assisted, or otherwise), or any other such techniques known to be suitable for forming features (e.g., holes) through a thickness of the glass may be employed to achieve a desired diameter and feature pitch.

A laser assisted etching technique may be used to sensitize etch the glass initially. In an embodiment, a conductive layer may be formed within the TGV. In an embodiment, the conductive layer may comprise copper or copper alloy materials. In an embodiment, a copper seed layer may be initially deposited (using any suitable deposition processes) on the organic dielectric layer, and then copper may be plated on the seed layer, such that the TGV is filled with the conductive layer. The conductive filled TGV provides vertical electrical connections and facilitates heat dissipation for the package substrate. In some embodiments, the TGV may not be formed adjacent the one or more trenches so that the glass substrate does not comprise a TGV.

At step 508, the glass substrate may be placed within a portion of a package substrate. In an embodiment, the glass substrate comprising the one or more trenches filled with conductive material may be singulated from a glass panel and then embedded into the package substrate. In an embodiment, the glass substrate may be placed within a core layer of the package substrate or may be placed within a build-up layer or within build up layers of the package substrate, as depicted in any of the embodiments herein.

FIG. 6 illustrates an electronic or computing device 600 in accordance with one or more implementations of the present description. The computing device 600 may include a housing 601 having a board 602 disposed therein. The computing device 600 may include a number of integrated circuit components, including but not limited to a processor 604, at least one communication chip 606A, 606B, volatile memory 608 (e.g., DRAM), non-volatile memory 610 (e.g., ROM), flash memory 612, a graphics processor or CPU 614, a digital signal processor (not shown), a crypto processor (not shown), a chipset 616, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 602. In some implementations, at least one of the integrated circuit components may be a part of the processor 604.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory. At least one of the integrated circuit components may include an apparatus having a glass substrate comprising one or more trenches, the trenches extending through a portion of the glass substrate, wherein the glass substrate is embedded within a portion of the package substrate, and wherein the one or more conductive interconnect structures are coupled with the one or more trenches.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure. It is understood that the subject matter of the present description is not necessarily limited to specific applications illustrated in FIGS. 1-6. The subject matter may be applied to other integrated circuit devices and assembly applications, as well as any appropriate electronic application, as will be understood to those skilled in the art.

The following examples pertain to further embodiments and specifics in the examples may be used anywhere in one or more embodiments, where a first example is an apparatus comprising: a package substrate; a glass substrate embedded within the package substrate, the glass substrate comprising: a first portion of the glass substrate comprising: one or more trenches extending within the first portion, the one or more trenches comprising a first conductive layer on individual trench sidewalls of the one or more trenches; a dielectric layer on the first conductive layer; and a second conductive layer on the dielectric layer; and a second portion of the glass substrate below the first portion.

In second examples the first example further comprises wherein the one or more trenches comprise a first set of trenches within a first side of the glass substrate, and wherein a second set of trenches is on a second side of the glass substrate, opposite the first side of the glass substrate.

In third examples wherein any of examples 1-2 further comprises wherein the conductive layer comprises copper or a copper alloy, and wherein the second portion of the glass substrate is free of the one or more trenches.

In fourth examples wherein any of examples 1-3 further comprises wherein individual ones of the one or more trenches comprise a trench opening, wherein a lateral width of the trench opening is between 1 micron to 15 microns.

In fifth examples wherein any of examples 1-4 further comprises wherein the glass substrate is embedded in a core portion of the package substrate, and wherein a thickness of the glass substrate is between 100 microns to 2000 microns.

In sixth examples wherein example 5 further comprises wherein a first side of the glass substrate is coplanar with a first side of the core portion of the package substrate, and a second side of the glass substrate is coplanar with a second side of the core portion of the package substrate.

In seventh examples wherein example 5 further comprises wherein an encapsulant material is between the glass substrate and the core material.

In eighth examples wherein any of examples 1-7 further comprises wherein a through glass via (TGV) extends through the glass substrate and is adjacent the one or more trenches, wherein the TGV is filled with a conductive material.

In ninth examples wherein any of examples 1-8 further comprises wherein a through glass via (TGV) extends through the glass substrate and is adjacent the one or more trenches, wherein the TGV is filled with a conductive material.

In tenth examples wherein any of examples 1-9 further comprise wherein the glass substrate comprises a thickness of 100 microns to 2000 microns and comprises a rectangular shape in plan view.

In eleventh examples wherein any of examples 1-10 further comprise a die conductively coupled to the one or more trenches.

In twelfth examples wherein any of examples 1-11 further comprise wherein the glass substrate comprises a deep trench capacitor structure.

Example thirteen is an apparatus, comprising: a package substrate comprising one or more conductive interconnect structures; and a glass substrate comprising one or more trenches, the trenches extending through a first portion of a thickness of the glass substrate, wherein the glass substrate is embedded within a portion of the package substrate, and wherein the one or more conductive interconnect structures are coupled with one or more capacitor structures in the one or more trenches, and wherein a second portion of the thickness of the glass substrate extends below the first portion.

In fourteenth examples wherein example 13 further comprises wherein the one or more trenches comprise a first set of trenches on a first side of the glass substrate, and wherein a second set of trenches is on a second side of the glass substrate, opposite the first side of the glass substrate.

In fifteenth examples wherein any of examples 13-14 further comprise wherein the glass substrate comprises a first glass substrate with a first set of trenches, and wherein a second glass substrate comprising a second set of trenches is coupled to the first glass substrate.

In sixteenth examples wherein example 15 further comprises wherein the first glass substrate is hybrid bonded to the second glass substrate, wherein a through glass via extends through the first glass substrate and the second glass substrate.

In seventeenth examples wherein any of examples 13-16 further comprise a die coupled to the package substrate.

An eighteenth example is a method comprising: forming one or more trenches in a glass substrate; forming a conductive layer on a sidewall of the one or more trenches; forming a through glass via through the glass substrate adjacent to the one or more trenches; and placing the glass substrate within a portion of a package substrate.

In nineteenth examples, example 18 further comprises placing the glass substrate in a core layer of the package substrate or a build up layer of the package substrate.

In twentieth examples, any of examples 18-19 further comprises placing a die on a surface of the package substrate, wherein the one or more trenches are coupled to the die.

It will be recognized that principles of the disclosure are not limited to the embodiments so described but can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An apparatus, comprising:
a package substrate;
a glass substrate embedded within the package substrate, the glass substrate comprising:
a first portion of the glass substrate comprising:
one or more trenches extending within the first portion, the one or more trenches comprising a first conductive layer on individual trench sidewalls of the one or more trenches;
a dielectric layer on the first conductive layer; and
a second conductive layer on the dielectric layer; and
a second portion of the glass substrate below the first portion.

2. The apparatus of claim 1, wherein the one or more trenches comprise a first set of trenches within a first side of the glass substrate, and wherein a second set of trenches is on a second side of the glass substrate, opposite the first side of the glass substrate.

3. The apparatus of claim 1, wherein at least one of the first conductive layer or the second conductive layer comprises copper or a copper alloy, and wherein the second portion of the glass substrate is free of the one or more trenches.

4. The apparatus of claim 1, wherein individual ones of the one or more trenches comprise a trench opening, wherein a lateral width of the trench opening is between 1 micron to 15 microns.

5. The apparatus of claim 1, wherein the glass substrate is embedded in a core portion of the package substrate, and wherein a thickness of the glass substrate is between 100 microns to 2000 microns.

6. The apparatus of claim 5, wherein a first side of the glass substrate is coplanar with a first side of the core portion of the package substrate, and a second side of the glass substrate is coplanar with a second side of the core portion of the package substrate.

7. The apparatus of claim 5, wherein an encapsulant material is between the glass substrate and the core portion.

8. The apparatus of claim 1, wherein the glass substrate is embedded within a build up portion of the package substrate, and wherein a thickness of the glass substrate is between 25 microns to 100 microns.

9. The apparatus of claim 1, wherein a through glass via (TGV) extends through the glass substrate and is adjacent the one or more trenches, wherein the TGV is filled with a conductive material.

10. The apparatus of claim 1, wherein the glass substrate comprises a thickness of 100 microns to 2000 microns and comprises a rectangular shape in plan view.

11. The apparatus of claim 1, further comprising a die conductively coupled to the one or more trenches.

12. The apparatus of claim 1 wherein the glass substrate comprises a deep trench capacitor structure.

13. An apparatus, comprising:
a package substrate comprising one or more conductive interconnect structures; and
a glass substrate comprising one or more trenches, the trenches extending through a first portion of a thickness of the glass substrate, wherein the glass substrate is embedded within a portion of the package substrate, and wherein the one or more conductive interconnect structures are coupled with one or more capacitor structures in the one or more trenches, and wherein a second portion of the thickness of the glass substrate extends below the first portion.

14. The apparatus of claim 13, wherein the one or more trenches comprise a first set of trenches on a first side of the glass substrate, and wherein a second set of trenches is on a second side of the glass substrate, opposite the first side of the glass substrate.

15. The apparatus of claim 13, wherein the glass substrate comprises a first glass substrate with a first set of trenches, and wherein a second glass substrate comprising a second set of trenches is coupled to the first glass substrate.

16. The apparatus of claim 15, wherein the first glass substrate is hybrid bonded to the second glass substrate, wherein a through glass via extends through the first glass substrate and the second glass substrate.

17. The apparatus of claim 13, further comprising a die coupled to the package substrate.

18. A method, comprising:
forming one or more trenches in a glass substrate;
forming a conductive layer on a sidewall of the one or more trenches;
forming a through glass via through the glass substrate adjacent to the one or more trenches;
and
placing the glass substrate within a portion of a package substrate.

19. The method of claim 18, further comprising placing the glass substrate in a core layer of the package substrate or a build up layer of the package substrate.

20. The method of claim 18, further comprising placing a die on a surface of the package substrate, wherein the one or more trenches are coupled to the die.
